(19) United States
(12) Patent Application Publication
(10) Pub. No.: US 2021/0296140 A1
(43) Pub. Date: Sep. 23, 2021

(54) DOUBLE TUBE STRUCTURE FLOW CELL APPARATUS

(71) Applicants: ZEUS CO., LTD., Hwaseong-si (KR); ZEUS ENP CO., LTD., Sejong-si (KR)

(72) Inventors: Hyun Kook PARK, Ansan-si (KR); Seong Hwan PARK, Cheongju-si (KR)

(73) Assignees: ZEUS CO., LTD., Hwaseong-si (KR); ZEUS ENP CO., LTD., Sejong-si (KR)

(21) Appl. No.: 17/174,510

(22) Filed: Feb. 12, 2021

(30) Foreign Application Priority Data
Mar. 20, 2020 (KR) 10-2020-0034134

(51) Int. Cl. H01L 21/67; C25F 3/12

(52) U.S. Cl. CPC H01L 21/67017; C25F 3/12

(57) ABSTRACT

A double tube structure flow cell apparatus according to the present disclosure includes: a first flow path formation part connected to a medium inlet part such that a fluid medium is introduced into the medium inlet part and having a first flow path part such that the fluid medium flows in the first flow path part; a second flow path formation part having a second flow path part in communication with the first flow path part and connected to a medium discharge part such that the fluid medium of the second flow path part is discharged through the medium discharge part; and a bubble discharge part connected to the first flow path formation part to discharge air bubbles mixed with the fluid medium of the first flow path part.

### CROSS-REFERENCE TO RELATED APPLICATION

This application claims priority to and the benefit of Korean Patent Application No. 10-2020-0034134, filed on Mar. 20, 2020, the disclosure of which is incorporated herein by reference in its entirety.

### BACKGROUND

### 1. Field of the Invention

The present disclosure relates to a double tube structure flow cell apparatus, and more particularly, to a double tube structure flow cell apparatus that monitors the state of a fluid medium under use conditions of the fluid medium to accurately measure the concentration of the fluid medium.

### 2. Discussion of Related Art

In general, etching processes are performed in a process of manufacturing semiconductors such as semiconductor wafers and solar cells. In the etching process, high-temperature etching solutions (fluid medium) such as phosphoric acid solutions are used to etch silicon nitride films. Since an eluate, in which a material such as silicon of a semiconductor wafer is dissolved, is contained in the etching solution, the concentration of the eluate in the etching solution increases as the etching process for the semiconductor wafer progresses. When the concentration of the eluate in the etching solution is increased to more than a certain concentration, the etching solution is replaced.

Since it is difficult to analyze the concentration of silicon in trace amounts when the etching solution is at a high temperature, a part of the etching solution is collected and cooled to room temperature. In order to increase the detection sensitivity of the cooled etching solution, the concentration of the etching solution is detected after the etching solution is subjected to a chemical treatment a plurality of times.

However, in the related art, since the etching solution is cooled to room temperature and then subjected to the chemical treatment a plurality of times, the detection error range is increased according to the temperature difference of the etching solution. Thus, it is difficult to accurately predict the state of the etching solution under use conditions applied to actual semiconductor processes.

Further, since the eluate is easily precipitated from the etching solution when the high-temperature etching solution is cooled to room temperature, it may be difficult to accurately measure the concentration of the eluate in the etching solution.

Further, since the chemical treatment is performed a plurality of times in order to accurately measure the concentration of the etching solution, a matrix is complicated during the concentration analysis, and thus the accuracy of the analysis concentration is reduced.

The background art of the present disclosure is disclosed in Korean Patent No. 1785859 (registered on Sep. 29, 2017, Title of the invention: Fluorescent Silicon Nanoparticle for Detecting Copper Ion, Method for Preparing the Same, and Ion Detecting Sensor Using the Same).

### SUMMARY OF THE INVENTION

The purpose of the present disclosure is to provide a double tube structure flow cell apparatus that monitors the state of a fluid medium under use conditions of the fluid medium to accurately measure the concentration of the fluid medium.

A double tube structure flow cell apparatus according to the present disclosure includes: a first flow path formation part connected to a medium inlet part so that a fluid medium is introduced into the medium inlet part and having a first flow path part such that the fluid medium flows in the first flow path part; a second flow path formation part having a second flow path part in communication with the first flow path part and connected to a medium discharge part such that the fluid medium of the second flow path part is discharged through the medium discharge part; and a bubble discharge part connected to the first flow path formation part to discharge air bubbles mixed with the fluid medium of the first flow path part.

The second flow path formation part may be disposed inside the first flow path formation part.

The first flow path formation part may include: an outer housing to which the medium inlet part and the bubble discharge part are connected; and light transmission parts formed on both sides of the outer housing to transmit light.

The second flow path formation part may include: an inner housing of which both sides are open such that the first flow path part and the second flow path part communicate with each other and to which the medium discharge part is connected; and a bubble separation part formed on an outer surface of the inner housing.

The outer housing and the inner housing may be arranged in a double tube form.

The bubble discharge part may be disposed on an upper side of the outer housing to discharge the air bubbles separated from the fluid medium.

The bubble discharge part may be formed at each of both ends of the outer housing.

The bubble separation part may be formed at each of both ends of the inner housing.

The bubble discharge part may include: a bubble discharge line connected to the outer housing and a first pump; and an opening control valve installed in the bubble discharge line.

The cross-sectional area of the first flow path part may be larger than the cross-sectional area of the medium inlet part.

The double tube structure flow cell apparatus may further include a drain part connected to the first flow path formation part.

The drain part may include: a first drain line connected to the first flow path formation part and the medium discharge part; a first opening/closing valve installed in the first drain line; a second drain line branched off from the first drain line; and a second opening/closing valve installed in the second drain line.

The double tube structure flow cell apparatus according to the present disclosure may further include a monitoring unit configured to measure a state of the fluid medium by irradiating the fluid medium flowing along the second flow path part with light.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a perspective view schematically illustrating a double tube structure flow cell apparatus according to an embodiment of the present disclosure;

FIG. 2 is a sectional view schematically illustrating the double tube structure flow cell apparatus according to the embodiment of the present disclosure;

FIG. 3 is a sectional view schematically illustrating a flow state of a fluid medium in the double tube structure flow cell apparatus according to the embodiment of the present disclosure;

FIG. 4 is a sectional view illustrating a state in which the double tube structure flow cell apparatus according to the embodiment of the present disclosure is installed to be inclined to one side;

FIG. 5 is a sectional view illustrating a state in which the double tube structure flow cell apparatus according to the embodiment of the present disclosure is installed to be inclined to the other side;

FIG. 6 is a block diagram illustrating a state in which the double tube structure flow cell apparatus according to the embodiment of the present disclosure is applied to an etching apparatus according to a first embodiment;

FIG. 7 is a block diagram illustrating a state in which the double tube structure flow cell apparatus according to the embodiment of the present disclosure is applied to an etching apparatus according to a second embodiment;

FIG. 8 is a block diagram illustrating a state in which the double tube structure flow cell apparatus according to the embodiment of the present disclosure is applied to an etching apparatus according to a third embodiment; and

FIG. 9 is a block diagram illustrating a state in which the double tube structure flow cell apparatus according to the embodiment of the present disclosure is applied to an etching apparatus according to a fourth embodiment.

### DETAILED DESCRIPTION OF EXEMPLARY EMBODIMENTS

Hereinafter, embodiments of a double tube structure flow cell apparatus according to the present disclosure will be described with reference to the accompanying drawings. In the description of the double tube structure flow cell apparatus, the thickness of lines or the size of components illustrated in the drawings may be exaggerated for clarity and convenience of description. Further, terms described below are terms defined in consideration of functions in the present disclosure and may change according to the intention or custom of a user or an operator. Therefore, definitions of these terms should be made based on the contents throughout the present specification.

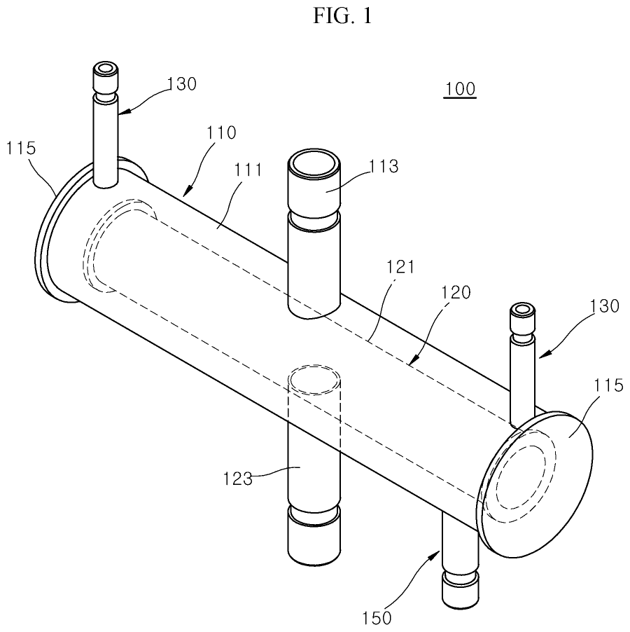

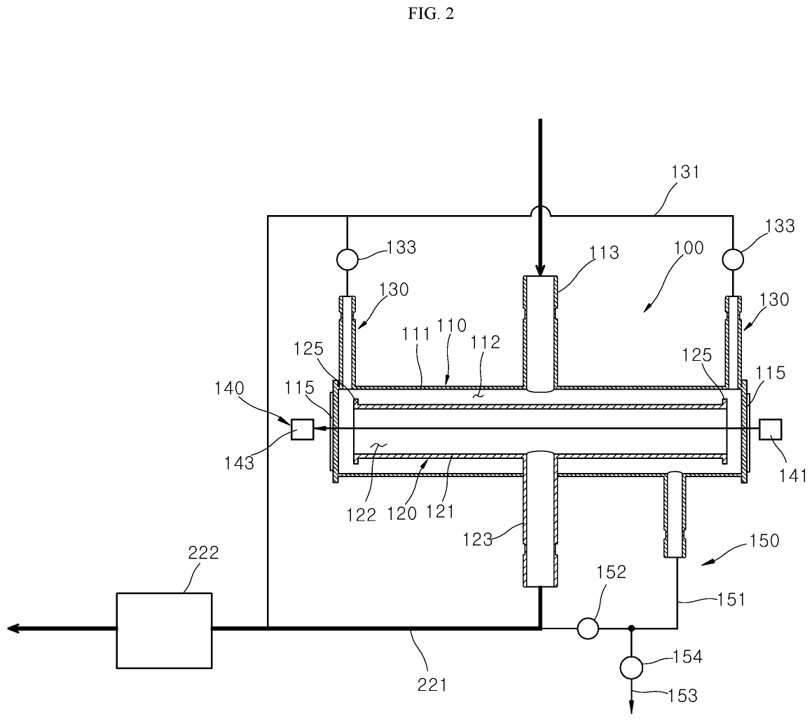

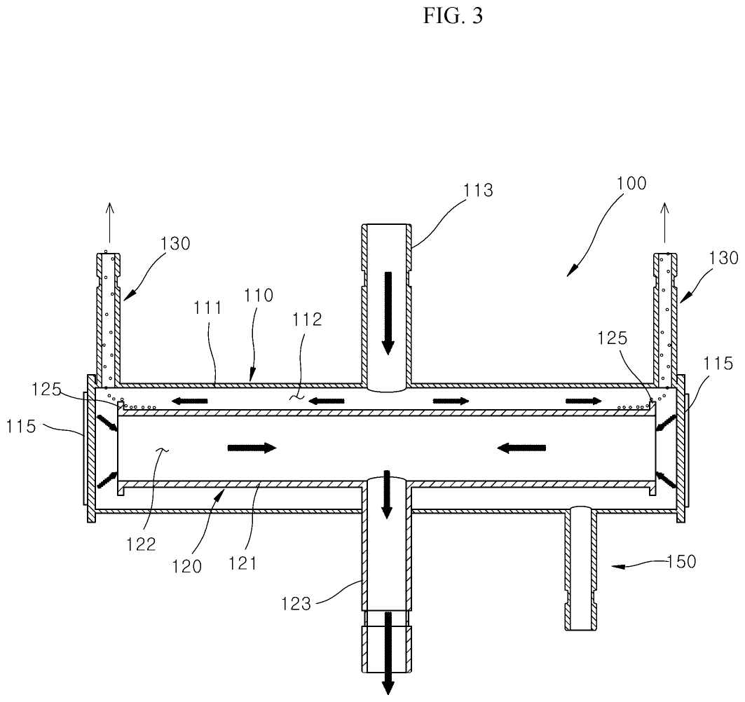

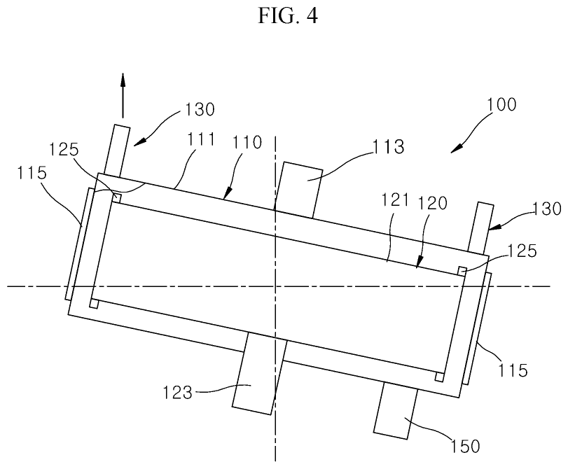

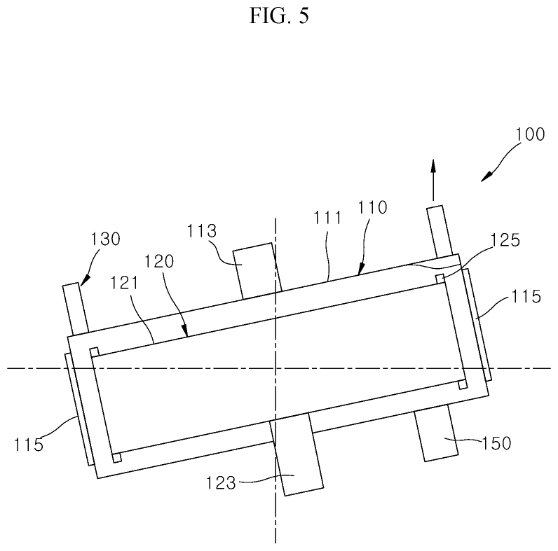

FIG. 1 is a perspective view schematically illustrating a double tube structure flow cell apparatus according to an embodiment of the present disclosure, FIG. 2 is a sectional view schematically illustrating the double tube structure flow cell apparatus according to the embodiment of the present disclosure, FIG. 3 is a sectional view schematically illustrating a flow state of a fluid medium in the double tube structure flow cell apparatus according to the embodiment of the present disclosure, FIG. 4 is a sectional view illustrating a state in which the double tube structure flow cell apparatus according to the embodiment of the present disclosure is installed to be inclined to one side, and FIG. 5 is a sectional view illustrating a state in which the double tube structure flow cell apparatus according to the embodiment of the present disclosure is installed to be inclined to the other side.

Referring to FIGS. 1 to 5, a double tube structure flow cell apparatus 100 according to the embodiment of the present disclosure includes a first flow path formation part 110, a second flow path formation part 120, bubble discharge parts 130, and a monitoring unit 140.

The double tube structure flow cell apparatus 100 according to the embodiment of the present disclosure may be applied to various fields such as a batch type processing device and a single type processing device for processing a semiconductor material such as a wafer or a solar cell, an apparatus for measuring the elution amount of an eluate, and an apparatus for measuring a change in the concentration of a solution.

The first flow path formation part 110, the second flow path formation part 120, and the bubble discharge part 130 may be made of any one of a quartz material, Pyrex glass, a Teflon material, and a sapphire material to prevent heat deformation and corrosion caused by a fluid medium having a temperature of about 150° C. to 200° C. The first flow path formation part 110, the second flow path formation part 120, and the bubble discharge part 130 may be made of a transparent material or an opaque material.

The fluid medium may be an etching solution used in a semiconductor process when a semiconductor wafer, a solar cell, or the like is manufactured. The etching solution may be a phosphoric acid solution having a temperature of 150° C. to 200° C.

The fluid medium heated to 150° C. to 200° C. may flow through the first flow path formation part 110 and the second flow path formation part 120 to suppress precipitation of substances contained in the fluid medium. Thus, since the fluid medium circulating in the semiconductor process is directly introduced into the first flow path formation part 110 and the second flow path formation part 120, the concentration of the fluid medium used in the semiconductor process may be measured in real time. Further, since it is not necessary to perform a chemical treatment a plurality of times after the fluid medium is cooled to room temperature, the occurrence of detection errors according to the temperature difference of the fluid medium can be prevented. Further, since it is not necessary to cool the high-temperature fluid medium to room temperature, the eluate may be prevented from being precipitated from the fluid medium.

A medium inlet part 113 is connected to the first flow path formation part 110 such that the fluid medium flows thereinto, and a first flow path part 112 is formed in the first flow path formation part 110 such that the fluid medium flows therein. The medium inlet part 113 may be connected to an etching apparatus for a semiconductor material.

A second flow path part 122 is formed in the second flow path formation part 120 to communicate with the first flow path part 112, and the second flow path formation part 120 is connected to a medium discharge part 123 such that the fluid medium of the second flow path part 122 is discharged.

The bubble discharge part 130 is connected to the first flow path formation part 110 to discharge air bubbles mixed with the fluid medium of the first flow path part 112. Since the bubble discharge part 130 is connected to the first flow path formation part 110, the air bubbles are removed while the fluid medium flows in the first flow path part 112 of the first flow path formation part 110, and the fluid medium then flows in the second flow path part 122 of the second flow path formation part 120.

The monitoring unit 140 measures a state of the fluid medium by irradiating the fluid medium flowing along the second flow path part 122 with light. The monitoring unit 140 may be connected to a controller in a wireless or wired manner. Since the monitoring unit 140 measures the state of the fluid medium by irradiating the fluid medium from which the air bubbles are removed with light, the light is prevented from being scattered and refracted by the air bubbles mixed in the fluid medium, and thus light loss may be reduced. Thus, since the monitoring unit 140 may accurately measure the state of the concentration of the fluid medium, the amount of mixed foreign materials, or the like, the controller may accurately determine the state of the fluid medium based on a signal received from the monitoring unit 140.

The monitoring unit 140 includes a light irradiation unit 141 that irradiates the second flow path part 122 of the second flow path formation part 120 with light and a light detection unit 143 that detects light having a specific wavelength which is absorbed by the fluid medium while the light passes through the fluid medium of the second flow path part 122. The light irradiation unit 141 is disposed outside one light transmission part 115, and the light detection unit 143 is disposed outside the other light transmission part 115. The light irradiation unit 141 and the light detection unit 143 may be arranged opposite to each other on both sides of the second flow path part 122. Since the light proceeds in a traveling direction of the fluid medium of the second flow path part 122, the scattering and refraction of the light by the air bubbles or the eluate are minimized when the light passes through the fluid medium, and thus the light loss may be reduced. Further, since the eluate contained in the fluid medium may smoothly absorb light having a specific wavelength while the light passes through the fluid medium, light detection efficiency may be improved.

The second flow path formation part 120 is disposed inside the first flow path formation part 110. Thus, the fluid medium from which the air bubbles are removed in the first flow path formation part 110 may be introduced into the second flow path formation part 120.

The first flow path formation part 110 includes an outer housing 111 to which the medium inlet part 113 and the bubble discharge part 130 are connected and the light transmission parts 115 formed on both sides of the outer housing 111 such that the light transmission parts 115 transmit light. The outer housing 111 may be formed of any one of glass, Pyrex glass, Teflon, sapphire, and the like. The outer housing 111 is formed in a cylindrical shape with both sides open, and the light transmission parts 115 are installed to close both sides of the outer housing 111. The light irradiated from the monitoring unit 140 passes through the light transmission parts 115.

The second flow path formation part 120 is open at both sides to allow the first flow path part 112 and the second flow path part 122 to communicate with each other and includes an inner housing 121 to which the medium discharge part 123 is connected and a bubble separation part 125 protruding from an outer surface of the inner housing 121. Since the bubble separation part 125 protrudes from the outer surface of the inner housing 121, the air bubbles flowing along the outer surface of the inner housing 121 may be easily separated from the outer surface of the inner housing 121 by the bubble separation part 125. Thus, the air bubbles separated from the first flow path part 112 are discharged to the outside of the first flow path formation part 110 through the bubble discharge part 130, and the fluid medium from which the air bubbles are removed in the first flow path part 112 may be introduced into the second flow path part 122.

The outer housing 111 and the inner housing 121 may be formed of the same material or different materials. Further, the light transmission parts 115 may be formed of the same material or a different material as or from the outer housing 111 or the inner housing 121.

The outer housing 111 and the inner housing 121 are arranged in a double tube form. In this case, the outer housing 111 and the inner housing 121 are formed in a cylindrical shape. Thus, the flow resistance of the fluid medium flowing along the outer housing 111 and the inner housing 121 may be reduced, and a stagnation section of the fluid medium may be prevented from occurring.

The bubble discharge part 130 is disposed on the upper side of the outer housing 111 to discharge the air bubbles separated from the fluid medium. A plurality of bubble separation parts 125 may be arranged on the upper side of the first flow path formation part 110. Since the separated air bubbles are lighter than the fluid medium, the air bubbles move to the upper side of the inner housing 121 and are then discharged to the outside of the first flow path formation part 110 through the bubble discharge part 130.

The bubble discharge parts 130 are formed at both ends of the outer housing 111. When the outer housing 111 is installed horizontally, air bubbles may be discharged through the bubble discharge parts 130 on both sides (see FIG. 3). Further, when the outer housing 111 is installed to be inclined, the air bubbles may be discharged through the bubble discharge parts 130 positioned higher (see FIGS. 4 and 5). Thus, even when the outer housing 111 is installed to be horizontal or inclined, the air bubbles separated from the fluid medium of the first flow path part 112 may be smoothly discharged.

The bubble discharge part 130 includes a bubble discharge line 131 connected to the outer housing 111 and a first pump 222 and an opening control valve 133 installed in the bubble discharge line 131. Since the bubble discharge line 131 is connected to the first pump 222, the air bubbles separated from the fluid medium may be discharged by a suction force of the first pump 222. Further, since an opening degree of the opening control valve 133 is adjusted, the fluid medium of the first flow path part 112 may be prevented from being discharged through the bubble discharge line 131.

The bubble separation parts 125 are formed at both ends of the inner housing 121. The bubble separation parts 125 may be formed in a circular ring shape at both ends of the inner housing 121. Further, the plurality of bubble separation parts 125 may be formed on both sides of the inner housing 121. Since air bubbles flowing along the outer surface of the inner housing 121 are separated by the bubble separation parts 125 at the ends of the inner housing 121, the air bubbles may be prevented from flowing into the second flow path part 122 of the inner housing 121. Further, when the fluid medium flows from the first flow path part 112 to the second flow path part 122, a flowing direction of the fluid medium is sharply changed near the ends of the inner housing 121 by about 180°, and thus the air bubbles may be separated more smoothly.

The cross-sectional area of the first flow path part 112 is larger than the cross-sectional area of the medium inlet part 113. Since the cross-sectional area of the first flow path part 112 is increased more sharply than the cross-sectional area of the medium inlet part 113, a turbulent flow may be formed while the fluid medium of the medium inlet part 113 is introduced into the first flow path part 112. Further, the fluid medium may be expanded while flowing into the first flow path part 112. Thus, the stagnation section of the fluid medium of the first flow path part 112 may be minimized, and air bubbles mixed with the fluid medium may be smoothly separated from the fluid medium. Further, since the turbulent flow is formed while the fluid medium of the medium inlet part 113 is introduced into the first flow path part 112, phosphoric acid and water contained in the fluid medium may be more uniformly mixed.

The cross-sectional area of the second flow path part 122 is larger than the cross-sectional area of the first flow path part 112. Since the cross-sectional area of the second flow path part 122 increases more sharply than the cross-sectional area of the first flow path part 112, a turbulent flow may be formed while the fluid medium of the first flow path part 112 is introduced into the second flow path part 122. Further, the fluid medium may be expanded while flowing into the second flow path part 122. Thus, air bubbles mixed with the fluid medium on an inlet side of the second flow path part 122 may be separated from the fluid medium. Further, since the turbulent flow is formed while the fluid medium of the first flow path part 112 is introduced into the second flow path part 122, phosphoric acid and water contained in the fluid medium may be more uniformly mixed.

The medium inlet part 113 is disposed on the upper side of the first flow path formation part 110, and the medium discharge part 123 is disposed on the lower side of the second flow path formation part 120. Thus, since the entire flowing direction of the fluid medium is directed to the lower side, the flowing direction of the fluid medium may be formed opposite to a separation direction of the air bubbles.

The medium inlet part 113 is disposed in the center of the first flow path formation part 110 in a lengthwise direction, and the medium discharge part 123 is disposed in the center of the second flow path formation part 120 in the lengthwise direction. The fluid medium of the first flow path part 112 is divided and flows to both sides of the first flow path formation part 110, and the fluid medium flowing to both sides of the first flow path formation part 110 is collected at the center of the second flow path part 122.

The double tube structure flow cell apparatus 100 further includes a drain part 150 connected to the first flow path formation part 110. The drain part 150 is disposed on the lower side of the first flow path formation part 110. Since the drain part 150 is connected to the first flow path formation part 110, the fluid medium accommodated in the first flow path formation part 110 and the second flow path formation part 120 may be discharged through the drain part 150 when the double tube structure flow cell apparatus 100 is cleaned.

The drain part 150 includes a first drain line 151 connected to the first flow path formation part 110 and the medium discharge part 123, a first opening/closing valve 152 installed in the first drain line 151, a second drain line 153 branched off from the first drain line 151, and a second opening/closing valve 154 installed in the second drain line 153. When the semiconductor process progresses, the first opening/closing valve 152 is opened and the second opening/closing valve 154 is closed. Further, when the fluid medium is discharged to clean the double tube structure flow cell apparatus 100, the first opening/closing valve 152 is closed and the second opening/closing valve 154 is opened.

A first embodiment of the etching apparatus to which the double tube structure flow cell apparatus according to the embodiment of the present disclosure is applied will be described.

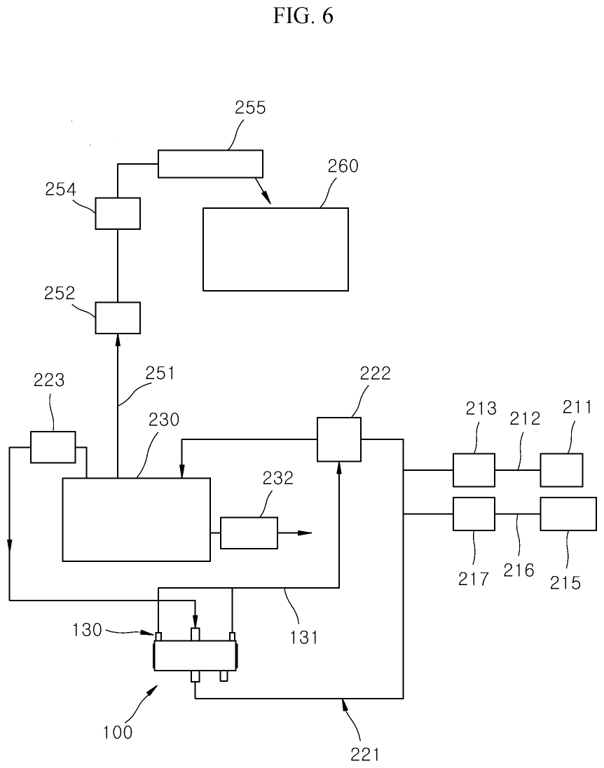

FIG. 6 is a block diagram illustrating a state in which the double tube structure flow cell apparatus according to the embodiment of the present disclosure is applied to the etching apparatus according to the first embodiment.

Referring to FIG. 6, a phosphoric acid supply line 212 is connected to a phosphoric acid supply unit 211, and a first valve 213 is connected to the phosphoric acid supply line 212. An additive supply line 216 is connected to an additive supply unit 215, and a second valve 217 is connected to the additive supply line 216.

A circulation line 221 is connected to the phosphoric acid supply line 212 and the additive supply line 216, and a mixing tank 230 is connected to the circulation line 221. The first pump 222 is connected to one side of the circulation line 221, and a third valve 223 is connected to the other side of the circulation line 221. Phosphoric acid and an additive supplied from the phosphoric acid supply unit 211 and the additive supply unit 215 are mixed inside the mixing tank 230. The phosphoric acid and the additive are mixed to form a fluid medium.

A supply line 251 is connected to the mixing tank 230, and a second pump 252, a heater 254, and a spray nozzle 255 are sequentially connected to the supply line 251. The spray nozzle 255 sprays the fluid medium into a wafer processing tank 260. A wafer is processed in the wafer processing tank 260.

The operation of the first embodiment of the etching apparatus described above will be described.

The first pump 222 is operated and the first valve 213 is opened to supply phosphoric acid to the mixing tank 230, and when the phosphoric acid is completely supplied to the mixing tank 230, the first valve 213 is closed. The second valve 217 is opened to supply an additive to the mixing tank 230, and when the additive is completely supplied to the mixing tank 230, the second valve 217 is closed.

The third valve 223 is closed, and the phosphoric acid and the additive in the mixing tank 230 flow along the circulation line 221 by a pumping pressure of the first pump 222. The phosphoric acid and the additive flow along the circulation line 221. The phosphoric acid and the additive of the circulation line 221 are introduced into the double tube structure flow cell apparatus 100, and the double tube structure flow cell apparatus 100 monitors the mixed concentration of the phosphoric acid and the additive.

In this case, the fluid medium of the medium inlet part 113 is introduced into the first flow path part 112 and air bubbles thereof are then removed. The air bubbles of the fluid medium of the first flow path part 112 are removed and the fluid medium is then introduced into the second flow path part 122. Further, the monitoring unit 140 measures the concentration of the high-temperature fluid medium of the second flow path part 122 as the second flow path part 122 is irradiated with light.

When the controller determines that the fluid medium is mixed at a preset concentration, the controller drives the second pump 252. When the second pump 252 is driven, the fluid medium in the mixing tank 230 flows along the supply line 251. The fluid medium of the supply line 251 is heated by the heater 254 and then sprayed into the wafer processing tank 260 through the spray nozzle 255.

Next, a second embodiment of the etching apparatus to which the double tube structure flow cell apparatus according to the embodiment of the present disclosure is applied will be described. Since the second embodiment is substantially the same as the first embodiment except for an outer tank 262 and a recovery line 265, the description of the same configuration as the first embodiment will be omitted, and features of the second embodiment will be described.

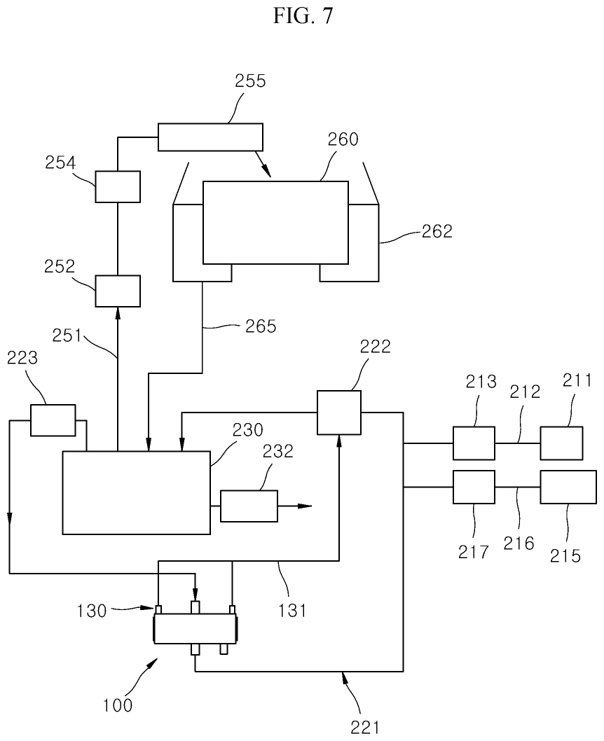

FIG. 7 is a block diagram illustrating a state in which the double tube structure flow cell apparatus according to the embodiment of the present disclosure is applied to an etching apparatus according to a second embodiment.

Referring to FIG. 7, the outer tank 262 is installed outside the wafer processing tank 260, and the outer tank 262 and the mixing tank 230 are connected to the recovery line 265. In this case, the double tube structure flow cell apparatus 100 is connected to the circulation line 221.

The fluid medium in the wafer processing tank 260 processes a wafer, overflows an upper side of the wafer processing tank 260, and is then introduced into the outer tank 262. The fluid medium collected in the outer tank 262 is recovered in the mixing tank 230 again through the recovery line 265.

Meanwhile, when phosphoric acid and an additive in the mixing tank 230 are mixed while flowing along the circulation line 221, the double tube structure flow cell apparatus 100 measures the mixed concentration of the phosphoric acid and the additive. Further, when the fluid medium in the outer tank 262 is recovered in the mixing tank 230 through the recovery line 265, the concentration of the fluid medium is changed by an eluate such as silica eluted from the wafer. In this case, the fluid medium in the mixing tank 230 may be introduced into the double tube structure flow cell apparatus 100 as the first pump 222 is driven, and the monitoring unit 140 of the double tube structure flow cell apparatus 100 may measure a change in the concentration of the fluid medium by irradiating the fluid medium with light.

Thus, the double tube structure flow cell apparatus 100 may measure the mixed concentration of the phosphoric acid and the additive before a wafer processing process starts and may measure a change in the concentration of the fluid medium while the wafer processing process progresses.

Next, a third embodiment of the etching apparatus to which the double tube structure flow cell apparatus according to the embodiment of the present disclosure is applied will be described.

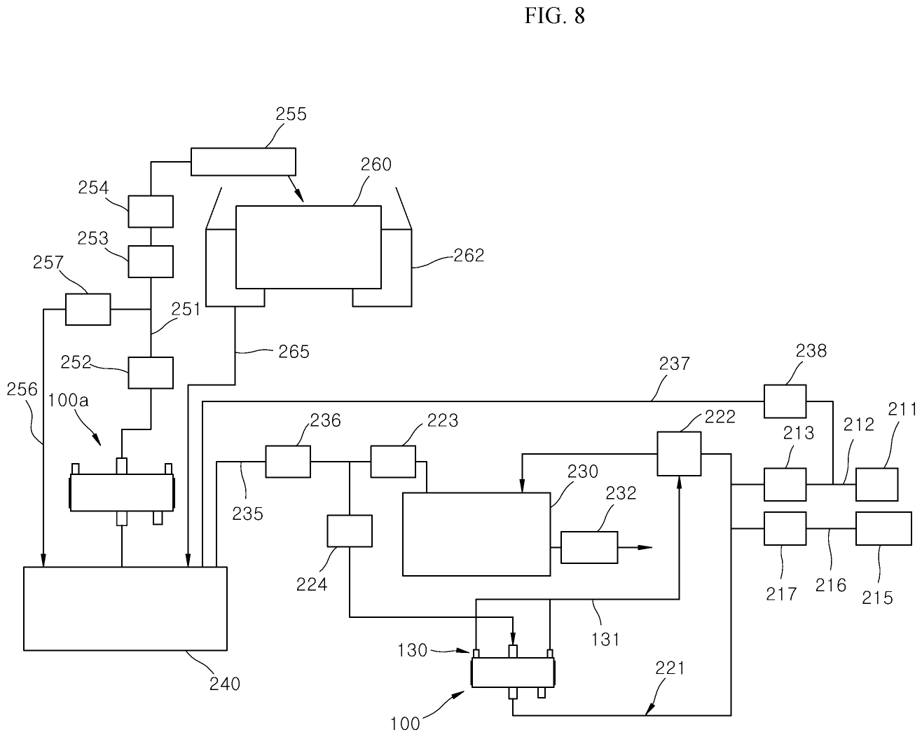

FIG. 8 is a block diagram illustrating a state in which the double tube structure flow cell apparatus according to the embodiment of the present disclosure is applied to an etching apparatus according to a third embodiment.

Referring to FIG. 8, the phosphoric acid supply line 212 is connected to the phosphoric acid supply unit 211, and the first valve 213 is connected to the phosphoric acid supply line 212. The additive supply line 216 is connected to the additive supply unit 215, and the second valve 217 is connected to the additive supply line 216.

The circulation line 221 is connected to the phosphoric acid supply line 212 and the additive supply line 216, and the mixing tank 230 is connected to the circulation line 221. The first pump 222 is connected to one side of the circulation line 221, and the third valve 223 and a fourth valve 224 are connected to the other side of the circulation line 221. Phosphoric acid and an additive supplied from the phosphoric acid supply unit 211 and the additive supply unit 215 are mixed inside the mixing tank 230. The phosphoric acid and the additive are mixed to form a fluid medium. A first double tube structure flow cell apparatus 100 is installed in the circulation line 221.

A connection line 235 is connected to the circulation line 221, and a fifth valve 236 is installed in the connection line 235. A medium supply tank 240 is installed in the connection line 235, and the medium supply tank 240 and the phosphoric acid supply line 212 are connected to a phosphoric acid addition line 237. A sixth valve 238 is installed in the phosphoric acid addition line 237.

The supply line 251 is connected to the medium supply tank 240, and a second double tube structure flow cell apparatus 100a, the second pump 252, a seventh valve 253, the heater 254, and a spray nozzle 255 are sequentially installed in the supply line 251. Further, a branch line 256 is branched off in a section between the second pump 252 and the seventh valve 253 in the supply line 251, and the branch line 256 is connected to the medium supply tank 240. An eighth valve 257 is installed in the branch line 256.

The outer tank 262 is installed outside the wafer processing tank 260, and the outer tank 262 and the medium supply tank 240 are connected to the recovery line 265.

The operation of the third embodiment of the etching apparatus described above will be described.

The first pump 222 is operated and the first valve 213 is opened to supply phosphoric acid to the mixing tank 230, and when the phosphoric acid is completely supplied to the mixing tank 230, the first valve 213 is closed. The second valve 217 is opened to supply an additive to the mixing tank 230, and when the additive is completely supplied to the mixing tank 230, the second valve 217 is closed.

The third valve 223 and the fourth valve 224 are opened, the fifth valve 236 is closed, and the phosphoric acid and the additive in the mixing tank 230 flow along the circulation line 221 by a pumping pressure of the first pump 222. The phosphoric acid and the additive flow along the circulation line 221. The phosphoric acid and the additive of the circulation line 221 are introduced into the first double tube structure flow cell apparatus 100, and the first double tube structure flow cell apparatus 100 monitors the mixed concentration of the phosphoric acid and the additive.

In this case, the fluid medium of the medium inlet part 113 is introduced into the first flow path part 112 and air bubbles thereof are then removed. The air bubbles of the fluid medium of the first flow path part 112 are removed and the fluid medium is then introduced into the second flow path part 122. Further, the monitoring unit 140 measures the concentration of the high-temperature fluid medium of the second flow path part 122 as the second flow path part 122 is irradiated with light.

When the controller determines that the fluid medium is mixed at a preset concentration, the controller drives the second pump 252 and opens the fifth valve 236. When the second pump 252 is driven, the fluid medium in the mixing tank 230 is introduced into the medium supply tank 240 along the connection line 235.

As the seventh valve 253 is closed and the eighth valve 257 is opened, the fluid medium in the medium supply tank 240 flows along the second double tube structure flow cell apparatus 100a, the second pump 252, the eighth valve 257, and the branch line 256. In this case, the second double tube structure flow cell apparatus 100a measures the concentration of the fluid medium accommodated in the medium supply tank 240 and the concentration of the etched silica.

When the concentration of the fluid medium in the medium supply tank 240 falls within a preset range, the controller controls the eighth valve 257 to be closed and the seventh valve 253 to be opened. The fluid medium in the medium supply tank 240 flows along the supply line 251. The fluid medium of the supply line 251 is heated by the heater 254 and then sprayed into the wafer processing tank 260 through the spray nozzle 255. Further, when the concentration of the fluid medium in the medium supply tank 240 is adjusted, the sixth valve 238 is opened to replenish the phosphoric acid in the medium supply tank 240.

The fluid medium overflowing the wafer processing tank 260 is collected in the outer tank 262, and the fluid medium in the outer tank 262 is recovered to the mixing tank 230 through the recovery line 265.

Thus, the first double tube structure flow cell apparatus 100 may measure the mixed concentration of the phosphoric acid and the additive supplied to the mixing tank 230, and the second double tube structure flow cell apparatus 100a may measure a change in the concentration of the fluid medium and the concentration of the eluate in the medium supply tank 240 while the wafer processing process progresses.

Next, a fourth embodiment of the etching apparatus to which the double tube structure flow cell apparatus according to the embodiment of the present disclosure is applied will be described. The fourth embodiment is substantially the same as the third embodiment except for an installation form of the second double tube structure flow cell apparatus. Hereinafter, features of the fourth embodiment will be described.

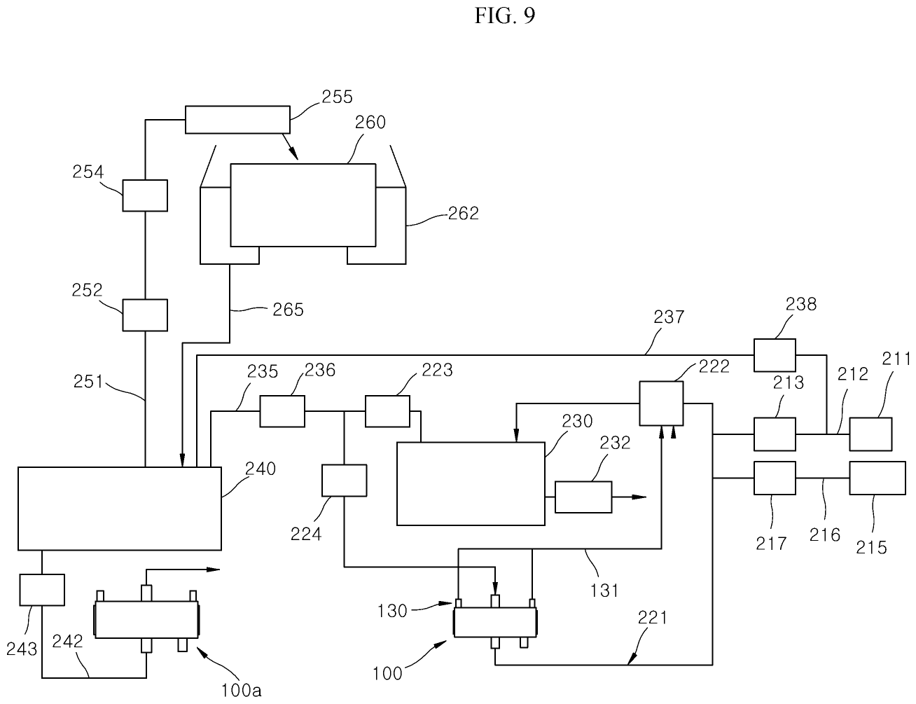

FIG. 9 is a block diagram illustrating a state in which the double tube structure flow cell apparatus according to the embodiment of the present disclosure is applied to an etching apparatus according to a fourth embodiment.

Referring to FIG. 9, a second discharge line 242 is connected to the medium supply tank 240, and a second discharge valve 243 and the second double tube structure flow cell apparatus 100a are installed in the second discharge line 242.

The fluid medium in the outer tank 262 is recovered to the medium supply tank 240 through the recovery line 265, and the fluid medium in the medium supply tank 240 is discharged through the second discharge line 242 at regular time intervals. A new fluid medium is supplied from the mixing tank 230 to the medium supply tank 240 in the amount of the fluid medium discharged from the medium supply tank 240.

The fluid medium of the second discharge line 242 is discharged to the outside after passing through the second double tube structure flow cell apparatus 100a. The second double tube structure flow cell apparatus 100a measures the concentration of the eluate such as silica in the fluid medium discharged through the second discharge line 242.

Thus, the first double tube structure flow cell apparatus 100 may measure the mixed concentration of the phosphoric acid and the additive supplied to the mixing tank 230, and the second double tube structure flow cell apparatus 100a may measure the concentration of the eluate contained in the medium supply tank 240 while the wafer processing process is progressed.

According to the present disclosure, since a high-temperature fluid medium flows in a double tube structure flow cell apparatus and light having a specific wavelength is absorbed by a fluid medium, the concentration of the fluid medium is measured under conditions used in an actual semiconductor process, and the fluid medium does not need to be chemically treated a plurality of times to increase the detection sensitivity of the fluid medium.

Further, according to the present disclosure, since a bubble discharge part is connected to a first flow path formation part, air bubbles are removed from the fluid medium while the fluid medium flows in a first flow path part of the first flow path formation part, and then the fluid medium is introduced into the second flow path part of the second flow path formation part. Thus, since the monitoring unit measures the state of the fluid medium by irradiating the fluid medium from which the air bubbles are removed with light, the light is prevented from being scattered and refracted by the air bubbles mixed in the fluid medium, and thus light loss can be reduced. Thus, the monitoring unit can accurately measure conditions such as the concentration of the fluid medium and the amount of mixed foreign materials.

Further, according to the present disclosure, the air bubbles flowing along an outer surface of an inner housing can be easily separated from the outer surface of the inner housing by a bubble separation part. Thus, the air bubbles separated in the first flow path part can be discharged to the outside of the first flow path formation part through the bubble discharge part, and the fluid medium from which the air bubbles are removed in the first flow path part can be introduced into the second flow path part.

Although the present disclosure has been described with reference to the embodiments illustrated in the drawings, the description is merely illustrative, and those skilled in the art to which the technology belongs could understand that various modifications and other equivalent embodiments may be made.

What is claimed is:

1. A double tube structure flow cell apparatus comprising:
a first flow path formation part connected to a medium inlet part such that a fluid medium is introduced into the medium inlet part and having a first flow path part such that the fluid medium flows in the first flow path part;
a second flow path formation part having a second flow path part in communication with the first flow path part and connected to a medium discharge part such that the fluid medium of the second flow path part is discharged through the medium discharge part; and
a bubble discharge part connected to the first flow path formation part to discharge air bubbles mixed with the fluid medium of the first flow path part.

2. The double tube structure flow cell apparatus of claim 1, wherein the second flow path formation part is disposed inside the first flow path formation part.

3. The double tube structure flow cell apparatus of claim 2, wherein the first flow path formation part includes:
an outer housing to which the medium inlet part and the bubble discharge part are connected; and
light transmission parts formed on both sides of the outer housing to transmit light.

4. The double tube structure flow cell apparatus of claim 3, wherein the second flow path formation part includes:
an inner housing of which both sides are open such that the first flow path part and the second flow path part communicate with each other and to which the medium discharge part is connected; and
a bubble separation part formed on an outer surface of the inner housing.

5. The double tube structure flow cell apparatus of claim 4, wherein the outer housing and the inner housing are arranged in a double tube form.

6. The double tube structure flow cell apparatus of claim 4, wherein the bubble discharge part is disposed on an upper side of the outer housing to discharge the air bubbles separated from the fluid medium.

7. The double tube structure flow cell apparatus of claim 6, wherein the bubble discharge part is formed at each of both ends of the outer housing.

8. The double tube structure flow cell apparatus of claim 7, wherein the bubble separation part is formed at each of both ends of the inner housing.

9. The double tube structure flow cell apparatus of claim 6, wherein the bubble discharge part includes:
a bubble discharge line connected to the outer housing and a first pump; and
an opening control valve installed in the bubble discharge line.

10. The double tube structure flow cell apparatus of claim 1, wherein a cross-sectional area of the first flow path part is larger than a cross-sectional area of the medium inlet part.

11. The double tube structure flow cell apparatus of claim 1, further comprising a drain part connected to the first flow path formation part.

12. The double tube structure flow cell apparatus of claim 11, wherein the drain part includes:
a first drain line connected to the first flow path formation part and the medium discharge part;
a first opening/closing valve installed in the first drain line;
a second drain line branched off from the first drain line; and
a second opening/closing valve installed in the second drain line.

13. The double tube structure flow cell apparatus of claim 1, further comprising a monitoring unit configured to measure a state of the fluid medium by irradiating the fluid medium flowing along the second flow path part with light.
